(19) United States
(12) Patent Application Publication
(10) Pub. No.: US 2023/0420364 A1
(43) Pub. Date: Dec. 28, 2023

(54) MICROELECTRONIC DIE WITH TWO DIMENSIONAL (2D) COMPLEMENTARY METAL OXIDE SEMICONDUCTOR DEVICES IN AN INTERCONNECT STACK THEREOF

(71) Applicant: Intel Corporation, Santa Clara, CA (US)

(72) Inventors: Kevin P. O'Brien, Portland, OR (US); Tristan A. Tronic, Aloha, OR (US); Ande Kitamura, Portland, OR (US); Ashish Verma Penumatcha, Beaverton, OR (US); Carl Hugo Naylor, Portland, OR (US); Chelsey Dorow, Portland, OR (US); Kirby Maxey, Hillsboro, OR (US); Scott B. Clendenning, Portland, OR (US); Sudarat Lee, Hillsboro, OR (US); Uygar E. Avci, Portland, OR (US)

(73) Assignee: Intel Corporation, Santa Clara, CA (US)

(21) Appl. No.: 17/849,207

(22) Filed: Jun. 24, 2022

(51) Int. Cl. H01L 23/528; H01L 23/522; H01L 29/423; H01L 29/18; H01L 27/092; H01L 29/786; H01L 29/66

(52) U.S. Cl. CPC H01L 23/5283; H01L 23/5226; H01L 29/42392; H01L 29/18; H01L 27/0924; H01L 29/78696; H01L 29/66742

(57) ABSTRACT

A microelectronic device, a semiconductor package including the device, an IC device assembly including the package, and a method of making the device. The device includes a substrate; a first structure on the substrate, the first structure corresponding to a front end of line (FEOL) stack of the device and including a plurality of first transistors therein; and a second structure on the substrate, the second structure corresponding to a back end of line (BEOL) stack of the device, and including a plurality of second transistors therein, the plurality of second transistors including a transition metal dichalcogenide (TMD) material. The second transistors are part of a voltage regulation architecture to regulate voltage supply to the die.

### TECHNICAL FIELD

This disclosure relates generally to voltage regulation for voltages supplied to microelectronic dies.

### BACKGROUND

Voltage regulation for microelectronic dies in a semiconductor package including a package coupled to the die currently include Complementary Metal Oxide Semiconductor (CMOS) transistors as part of the voltage regulation circuitry. The voltage regulation circuitry corresponds to a buck circuitry that includes capacitors and inductors on the package, and switches on the die.

A buck circuit used for voltage regulation for voltage supply to microelectronic dies provides a converter that typically steps down a direct current voltage to another, lower direct current voltage that is within a range of appropriate supply voltages for the die.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 is a schematic view of a circuit including an example of a standard voltage regulation (VR) architecture spread across a package substrate and a die.

FIG. 2 is a cross-sectional view of a semiconductor package corresponding to the circuit of FIG. 1 and including the VR architecture.

FIG. 3 is a cross sectional view of a semiconductor package according to an embodiment.

FIG. 4A is a cross sectional view of a two-dimensional (2D) NMOS transistor that may be used in the embodiment of FIG. 2.

FIG. 4B is a cross sectional view of a two-dimensional (2D) PMOS transistor that may be used in the embodiment of FIG. 2.

FIG. 5 is a schematic perspective view of a monolayer of a transition metal dichalcogenide crystal structure that may be used in a CMOS transistor of a VR architecture such as the one of FIG. 3.

FIG. 6 is a flow chart of a process according to some embodiments.

FIG. 7 is a cross-sectional side view of an integrated circuit device assembly that may include a semiconductor package in accordance with any of the embodiments disclosed herein.

FIG. 8 is a block diagram of an example electrical device that may include a semiconductor package in accordance with any of the embodiments disclosed herein.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

According to the state of the art, semiconductor packages that include a microelectronic device in the form of a die and a package substrate coupled to one another uses voltage regulation (VR) architectures to regulate voltage supply to the die. Such VR architectures may correspond to Buck circuits, and include silicon transistors on the die, such as complementary metal oxide semiconductor (CMOS) transistors, which transistors are typically used as switches of the Buck circuit. However, these transistors disadvantageously take up die real estate, and make a scaling of the die more difficult.

Some embodiments contemplate providing a die where transistors of a VR architecture that is to regulate voltage supply to a die (hereinafter “die VR architecture,” noting that the expression is not meant to necessarily indicate that the VR architecture itself is disposed (or not disposed) on the die) are within the back end of line (BEOL) region of a die, and preferably at a level of interconnect layers/metallization layers of the die, for example, at a level of a metal 1 (M1) layer, at a level of a metal 2 (M2) layer, at level of a metal 3 (layer).

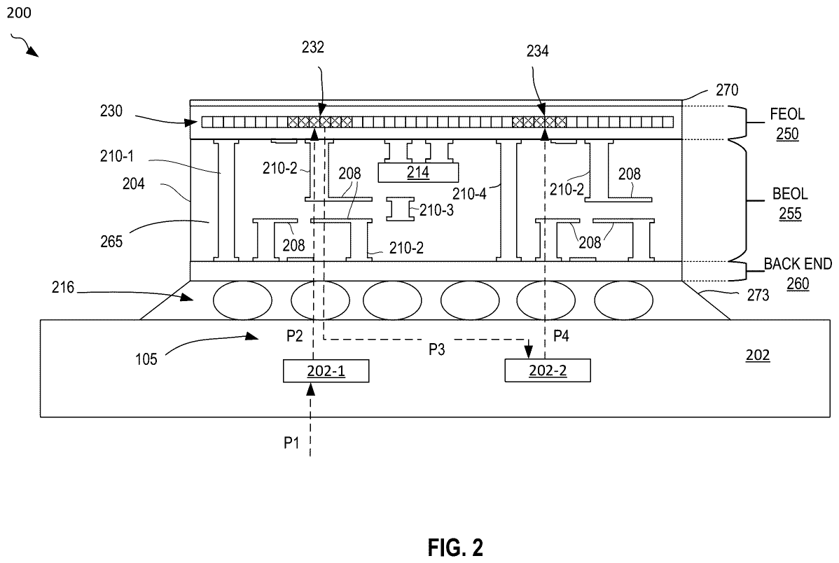

By “at a level of a metallization layer” in the context of the die's BEOL region, what is meant is at a position that, in a cross-sectional view of a die such as the one shown in FIG. 2 by way of example, corresponds to any location within a band that extends horizontally across a width of the die and that is bounded, at a top thereof, by a plane corresponding to a topmost surface of a given metallization layer of the die, and at a bottom thereof, by a plane corresponding to a bottom most surface of the given metallization layer of the die.

According to some embodiments, transistors that are part of a die VR architecture are in the BEOL region of the die, and preferably at least partially within a band defined by the metallization layers existing in the BEOL region.

A die comprises a large number of semiconductor devices, such as transistors, that are formed on a semiconductor substrate, such as one including Si. These devices are selectively interconnected by one or more patterned layers of a conductive material, typically aluminum or sometimes copper, to form circuits along with the devices to performs desired functions for the die. The patterned layers of conductive material are referred to as “metallization” layers. The BEOL region of the die corresponds to a region of the die that is between the front end of line (FEOL) region of the die where die transistors are typically located, and the backend of the die, which is a region of the die that is to be coupled to a package substrate.

Some embodiments further contemplate using transistors of the die VR architecture that include one or more transition metal dichalcogenicle (TMD) materials, such as, for example, MoS2, MoSe2, MoTe2, WS2, WSe2, WTE2.

By providing a VR architecture that includes transistors at a BEOL region of a die, advantageously, it is possible to either reduce the size of the die, as the real estate at the FEOL region currently used for VR transistors would no longer be needed, or to use a same size die with additional transistors in the FEOL region that are not used as part of the VR architecture, in this way ameliorating die functionality and performance. The above is possible without compromising the functionality of the VR architecture to regulate voltage supply to the die.

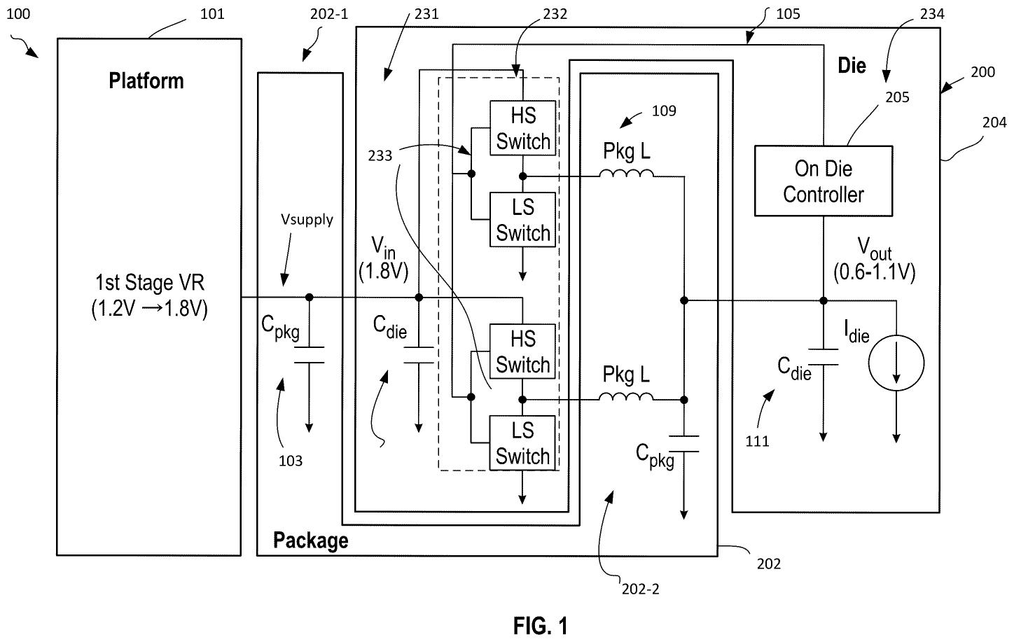

An explanation will now follow below regarding the state-of-the-art in the context of FIGS. 1 and 2.

FIG. 1 is a schematic view of an integrated circuit (IC) device assembly 100 according to the state of the art. IC device assembly 100 includes an example die VR architecture 105 in schematic form in a semiconductor package 200. The semiconductor package 200 includes a package substrate 202, and a die 204 that is coupled to the package 202. The semiconductor package 200 is coupled to a platform 101, such as a printed circuit board (PCB). VR architecture 105 provides an example of a Buck circuit to step down the voltage supply from the platform 101 to a voltage supply that is appropriate for the die. The Buck circuit, or Buck converter, corresponds to the VR architecture 105 and provides a step down voltage regulation circuitry that serves as a type of DC to DC converter. The VR architecture 105 is spread across the package substrate 202 and the die 204, and includes a package substrate capacitor portion 202-1, to which the supply voltage Vsupply is provided from platform 101. Vsupply may be between about 1.2V and about 1.8V in the shown example. The package substrate capacitor portion 202-1 of the VR architecture 105 may include one or more capacitors 103. VR architecture 105 further includes a first die capacitor portion 231 on the die 204, including one or more capacitors 107, and further a die switch region 232 including a plurality of die Switches. These die Switches may comprise field effect transistors (FET) or other types of transistors, such as CMOS transistors, including negative channel metal oxide semiconductor (NMOS) transistors, and positive channel MOS (PMOS) transistors. In the shown die Switch region 232 of VR architecture 105, there are shown high side (HS) transistors, or HS Switches, and low side (LS) transistors or LS Switches.

The LS Switches may include NMOS transistors, and the HS Switches PMOS transistors. For a NMOS transistor or NMOS Switch, the source typically is to be connected to ground, and the drain to a negative side of the load. For a PMOS transistor or PMOS Switch, the source typically is to be connected to a voltage source, such as Vin (1.8V in the shown example), and the drain is typically to be connected to the positive side of the load. Thus, a terminal (either source or drain) of a die Switch

A die switch of the VR architecture 105, as suggested in FIG. 1, has a terminal thereof coupled to inductors 109 within an inductor region 202-2 of the VR architecture 105, where the inductor region 202-2 is back on package substrate 202. The inductors 109 are coupled to a die controller region 234 of the VR architecture 105, which die controller region 234 is on the die 204, and includes a die controller circuitry 205, along with one or more capacitors 111. The output voltage from the VR architecture 105 is Vout, which in the shown example, is being between 0.6 and 1.1V to cause generation of a current Idie within the die circuitry.

As can be seen from FIG. 1, the VR architecture 105 includes circuitry that exists both on the package substrate 202 and on the die 204, and involves a signal to travel from the package substrate's capacitor region 202-1 to the die's die switch region 232, back to the package's inductor region 202-2, and back to the die's die controller region 234. It is to be noted that the VR architecture 105 of FIG. 1 is merely an example of a type of step down voltage regulation circuitry that could be used to step down the supply voltage to a die. In addition, VR architecture 105 may include more, less or different components than those shown in the figure.

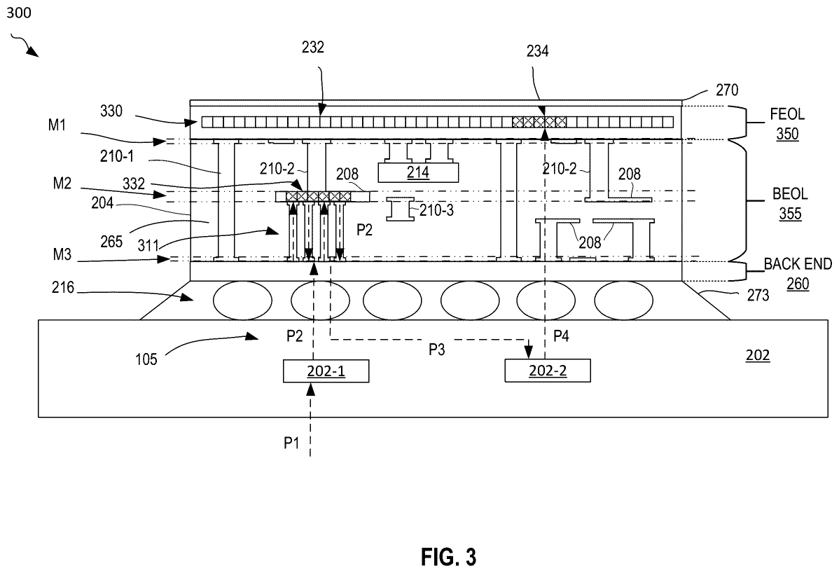

Many of the elements of the semiconductor package 100 of FIG. 1 are included in FIG. 2 relating to the state of the art, and in FIG. 3 relating to an example embodiment. A description of some elements may therefore not be repeated when discussing the drawings to be described below, and any of these elements may take any of the forms disclosed herein.

FIG. 2 is a cross-sectional view of a semiconductor package 200, corresponding to semiconductor package 200 of FIG. 1. Package substrate 202 corresponds substrate 202 of FIG. 1. The package substrate includes the package capacitor portion 202-1 of VR architecture 105, in addition to the package inductor portion 202-2 of VR architecture 105. Die 204 in FIG. 2 corresponds to die 204 of FIG. 1, and includes a front end-of-line stack 250 (FEOL 25), a back end-of-line 255 (BEOL 255), and a back end. 260. The die is bonded to the package substrate using solder balls 216 and an underfill material 273, such as epoxy.

FEOL stack 250 is built on a silicon wafer 270, and includes plurality of devices, such as active and passive devices (e.g. transistors, capacitors, resistors, etc.). For example, the FEOL stack 250 includes FinFET transistors therein, the transistors including die switches 233 as described in the context of FIG. 1. The transistors in the FEOL stack 250, including the die switches of VR architecture 105, may be formed using CMOS processing. As seen in FIG. 2, die switch region 232, corresponding to die switch region 232 of VR architecture 105 of FIG. 1, may include the die switches 233 similar to those shown in FIG. 1. In addition, FEOL stack 250 is shown as including the die controller portion 234 of VR architecture 105.

BEOL stack 255 of die 204 is disposed between the FEOL stack 250 and the back end 260. The BEOL stack 255 includes, in the shown example, four metallization layers M1, M2, M3 and M4, each of the metallization layers corresponding to conductive traces or interconnects within the die body. The BEOL stack 255 further includes a number of conductive vias therein, including through vias 210-2, blind vias 210-2, and embedded vias 210-3, and dielectric layers 265 between the metallization layers M1-M4 and the vias and embedding these conductive structures therein. BEOL further includes bonding sites (not shown) for chip-to-package connections, for example bonding sites in contact with solder balls 216, which provides a mechanical and electrical coupling of die 204 to the underlying package substrate 202.

The BEOL stack is formed as a second portion of die fabrication where the individual devices (transistors, capacitors, resistors, etc.) in the FEOL stack are interconnected with the metallization layers and the vias. Common metals are copper and aluminum. BEOL generally begins when the first layer of metal is deposited on a silicon wafer 270.

The die back end 260 includes a dielectric layer and electrically conductive structures (such as electrically conductive liners (not shown) in a solder ball contact region, to contact solder balls 216 for solder bonding, although dies may be bonded in any manner, such as through flip chip bonding, eutectic bonding, epoxy bonding, etc.).

As can be seen from FIG. 2, similar to FIG. 1, the VR architecture 105 includes circuitry that exists both on the package substrate 202 and on the die 204. VR architecture 205 receives Vsupply from a platform, such as platform 101 of FIG. 1 (now shown in Figs) from signal path P1. VR architecture 105 then requires the signal to travel, along a signal path P2, from the package substrate's capacitor region 202-1 to the die's die switch region 232, and back to the package's inductor region 202-2 along signal path P3. From the package's inductor region 202-2, the VR signal then travels along signal path P4 back to the die controller region 234. Signal paths P1-P4 may each include multiple electrically conductive structures and pathways, and not merely one. In addition, VR architecture 105 could include a different number of pathways than the four signal paths P1-P4 described.

FIG. 3 is a cross sectional view of a semiconductor package 300 according to an example embodiment. Package 300 is similar to package 200 described in the context of FIG. 2, except for a number of differences. For this reason, the same components as between FIGS. 2 and 3 have not again been described in detail in the context of FIG. 3.

A difference as between FIG. 3 and FIG. 2, by way of example, includes die switches 333 of FIG. 3 being in the BEOL stack 355 rather than in the FEOL stack 350 of die 204. In the shown embodiment of FIG. 3, in addition, the option is shown of including the die switches at a level of a metallization layer of the BEOL stack 355. In the shown example, die switches 333 are provided at the level of metallization layer M2, although the die could have any number of metallization layers, for example 10 or more, and the die switches 333 could be located at a level of any one or more of the metallization layers. In the embodiment of FIG. 3, the FEOL stack 350 does not include any die switches 333. In the shown embodiment, the die controller region 234, including one or more on-die controllers, one or more capacitors, and other circuit components, remains in the FEOL stack 350, although embodiments contemplate within their scope moving all die components of the VR architecture to the BEOL stack 355 as well, including the die controller region 234. Die switches 333 in FIG. 3 may be provided in the BEOL stack 355 either as a single layer of transistors, or as a multilayer stack of transistors. In addition, although die switch region 232 is shown as a single unitary region, embodiments include within their scope the provision of die switches 333 that are not necessarily spaced adjacent to one another in the BEOL stack 355, or not necessarily all at a same metallization level.

The portions of signal pathways P2 and P3 that exist on the die 204 and extend to and from the die switch region 232 may individually be embodied within die 204 as a cluster of electrically conductive structures, or an electrically conductive structure that is at least as thick as a power via of the die extending through the metallization layers. The cluster is to conduct an electrical signal a direction between the second transistors and the back end, the electrically conductive structures spaced more closely with respect to one another than a majority of other electrically conductive structures of the device that extend in the direction. The electrically conductive structures may include vias in the BEOL stack that extend in a cluster form in a direction toward the back end of the die. An example cluster 370 is shown in FIG. 3, although other configurations are possible.

A reason for the above optional configurations of the portions of the signal pathways P2 and P3 is to have electrically conductive structures coupled to and extending from the die switches 333 that offer reduced electrical resistance for signal to travel along pathways P2 and P3 to and from the die switches 333.

According to an embodiment, the portions of signal pathways P2 and P3 that are in the die 204 include electrically conductive structures (not shown) that extend separately to individual ones of the die switches 333, including to each NMOS and to each PMOS transistor.

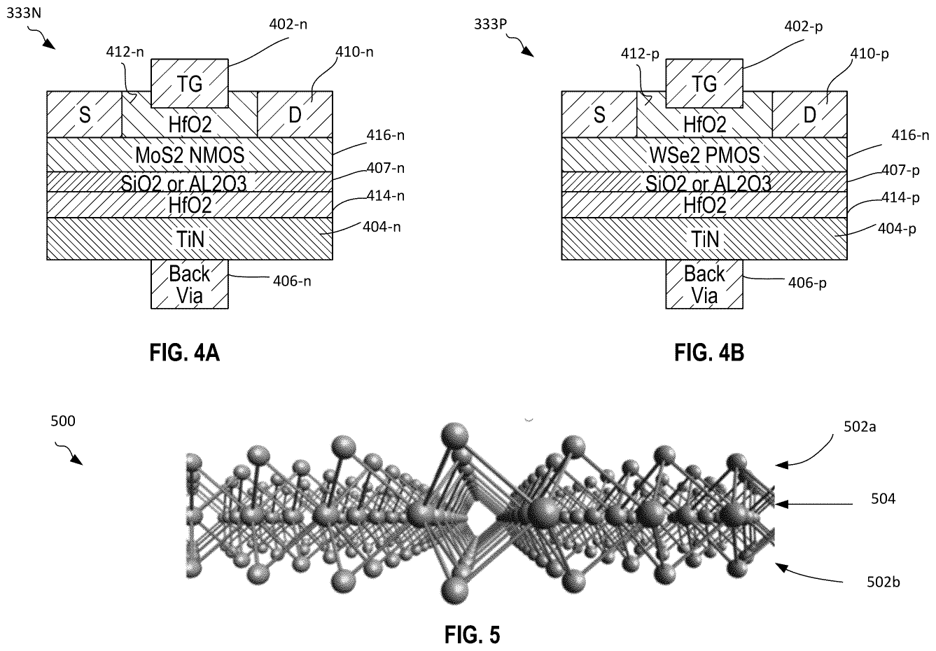

Another difference as between FIG. 3 and FIG. 2, by way of example, includes the option of the transistors of the die switches 333 in FIG. 3 including TMD materials. Examples of such transistors are provided in more detail in the context of FIGS. 4A and 4B described below.

FIG. 4A is a cross-sectional view of an example NMOS transistor 333-n that may be used as a die switch 333 in die switch region 232 of a VR architecture such a NMOS die switch of VR architecture 105 of FIG. 2. NMOS transistor 333-n is a field effect transistor (FET) that includes a TMD material, and, in the shown embodiment, corresponds to a dual gate transistor. NMOS 333-n includes a top gate 402-n, a bottom or back gate 404-n. Bottom gate is connected to a back via 406-n. A source region 408-n and a drain region 410-n are on opposite sides of the top gate 402-n and flank a top gate insulator structure 412-n, which, in the shown example, includes hafnium and oxide, HfO2. A bottom gate insulator structure 414-n is above the back gate 404-n, and, in the shown example, also includes hafnium and oxide in the form of HfO2. The NMOS 333-n has a channel 416-n that include a TMD material, in the shown example, MoS2. Between the TMD channel 416-n and the bottom gate insulator structure 414-n, optionally, an oxide layer 407-p may be placed, such as a silicon oxide or an aluminum oxide.

FIG. 4B is a cross-sectional view of an example PMOS transistor 333-p that may be used as a die switch 333 in die switch region 232 of a VR architecture such a PMOS die switch of VR architecture 105 of FIG. 2. PMOS transistor 333-p is a field effect transistor (FET) that includes a TMD material, and, in the shown embodiment, corresponds to a dual gate transistor. PMOS 333-p includes a top gate 402-p, a bottom or back gate 404-p. Bottom gate is connected to a back via 406-p. A source region 408-p and a drain region 410-p are on opposite sides of the top gate 402-p and flank a top gate insulator structure 412-p, which, in the shown example, includes hafnium and oxide, HfO2. A bottom gate insulator structure 414-p is above the back gate 404-p, and, in the shown example, also includes hafnium and oxide in the form of HfO2. The PMOS 333-p has a channel 416-p that include a TMD material, in the shown example, WSe2. Between the TMD channel 416-p and the bottom gate insulator structure 414-p, optionally, an oxide layer 407-p may be placed, such as a silicon oxide or an aluminum oxide.

Embodiments are however not limited to the use of dual gate MOSFETs as the die switches 333 of FIG. 3, but include within their scope the provision of any transistors, such as a planar FET, a dual gate FET, a trigate FET, a FinFET, a Gate All Around (GAA) FET to name a few. In addition, any suitable TMD material may be used for the NMOS gate, and any suitable TMD material may be used for the PMOS gate.

Reference will now be made to FIG. 5, which shows a schematic perspective view of an example TMD monolayer crystal structure 500. TMD crystal structure 500 is composed of three atomic planes 502a, 504 and 502b, where atomic planes 502a and 502b include a chalcogen (a material from group 16 of the periodic table, such as S, Se or Te, and middle atomic plane 504 include a metal from group 6 of the periodic table, such as Mo or W. A TMD monolayer often includes two atomic species: a metal atomic layer and two atomic layers including a chalcogen. The honeycomb, hexagonal lattice of crystal structure 500 may have threefold symmetry and, can permit mirror plane symmetry and/or inversion symmetry. In the macroscopic bulk crystal, or for an even number of monolayers, the crystal structure may have an inversion center. In the case of a monolayer (or any odd number of layers), the crystal may or may not have an inversion center.

According to some embodiments, the individual channels of the die switches of a VR architecture, similar to die switches 333 of FIGS. 3, 4A and 4B, may include 1, 2, 3, 4 or 5 TMD monolayers. Thus, by way of example, a six channel GAA transistor may have individual channels that include from 1 to 5 TMD monolayers according to some embodiments.

TMD channels advantageously provide better mobility than silicon at scaled channel thicknesses. In addition, whereas especially PMOS transistors with silicon channels are grown typically at temperatures of thousands of degrees, PMOS transistors using TMD channels may be grown at about 380 degrees centigrade, and typically at temperatures not to exceed about 400 degrees centigrade. Since metallization layers of a BEOL stack cannot withstand temperatures of above 400 degrees centigrade, providing transistors including TMD channels in the BEOL stack to server as switches of a VR architecture for the die are possible to implement effectively without compromising the integrity of the BEOL stack, while at the same time, advantageously allow transistors in the FEOL stack of a die to be repurposed for uses other than voltage regulation, or for the die to be altogether reduced in size.

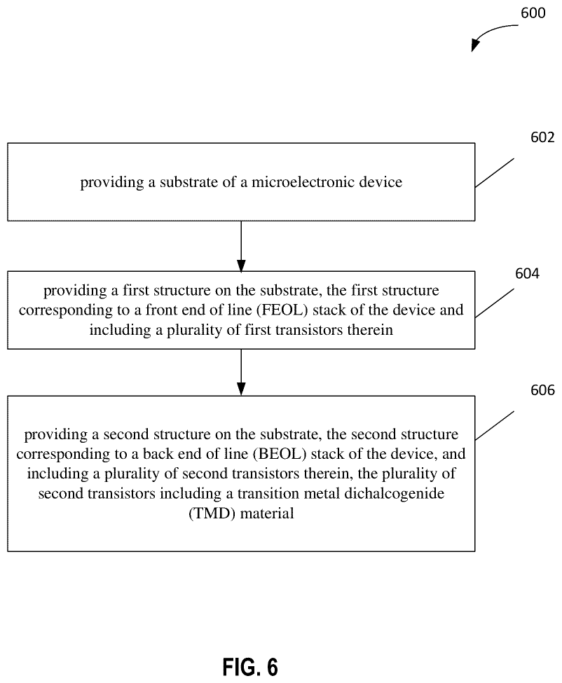

FIG. 6 shows a process 600 to fabricate a microelectronic device, such as die 204 of FIG. 3, according to some embodiments. At operation 402, the process includes providing a substrate of a microelectronic device. At operation 404, the process includes providing a first structure on the substrate, the first structure corresponding to a front end of line (FEOL) stack of the device and including a plurality of first transistors therein. At operation 406, the process includes providing a second structure on the substrate, the second structure corresponding to a back end of line (BEOL) stack of the device, and including a plurality of second transistors therein, the plurality of second transistors including a transition metal dichalcogenide (TMD) material.

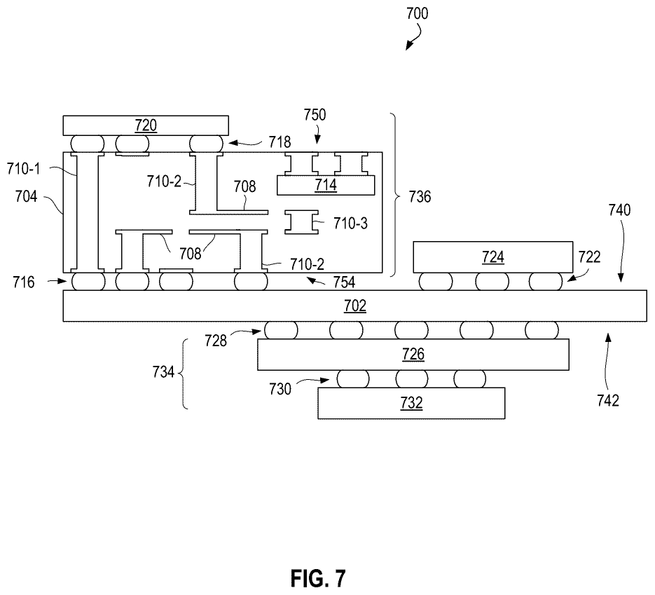

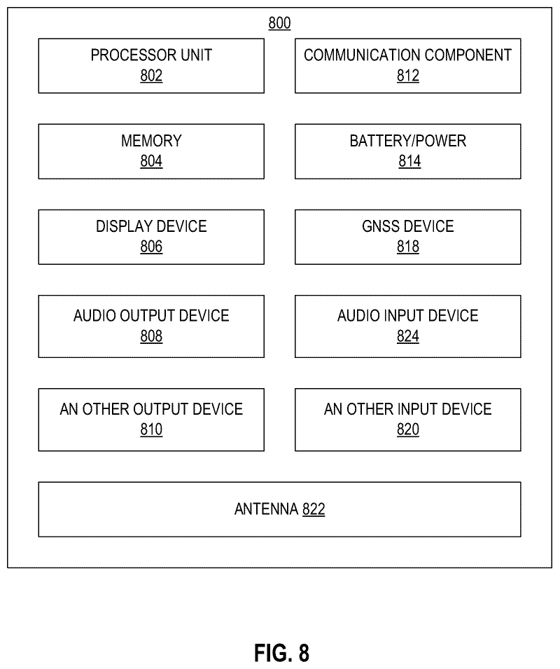

FIGS. 7 and 8 show some examples of an architecture that may include one or more semiconductor packages similar to the microelectronic assemblies described above in the context of embodiments as depicted by way of example in FIGS. 3, 4A and 4B.

FIG. 7 is a cross-sectional side view of an integrated circuit device assembly 700 that may include one or more integrated circuit structures each including any of the semiconductor packages of embodiments described herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiment MCPs disclosed herein. For example, any suitable ones of the components of the electrical device 800 may include one or more of the integrated circuit device assemblies 700, integrated circuit components 720, and/or embodiment MCPs disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TMDA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include one or more antennas, such as antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

The use of reference numerals separated by a “/”, such as “102/104” for example, is intended to refer to 102 or 104 as appropriate. Otherwise, the forward slash (“/”) as used herein means “and/or.”

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one MCP including an interposer bonded to a MCP subassembly through direct dielectric-to-dielectric bonding as described herein.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e. one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

As used herein, an “integrated circuit structure” or “may include one or more microelectronic dies.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### EXAMPLES

Some non-limiting example embodiments are set forth below.

Example 1 includes a microelectronic device including: a substrate; a first structure on the substrate, the first structure corresponding to a front end of line (FEOL) stack of the device and including a plurality of first transistors therein; and a second structure on the substrate, the second structure corresponding to a back end of line (BEOL) stack of the device, and including a plurality of second transistors therein, the plurality of second transistors including a transition metal dichalcogenide (TMD) material.

Example 2 includes the subject matter of Example 1, wherein the BEOL stack includes metallization layers, and the individual ones of the second transistor are at a level of one or more the metallization layers of the BEOL stack.

Example 3 includes the subject matter of Example 1, wherein the TMD material includes a monolayer comprising a top atomic layer, a middle atomic layer and a bottom atomic layer, the top atomic layer and the bottom atomic layer including a chalcogenide, and the middle atomic layer including a transition metal.

Example 4 includes the subject matter of Example 3, wherein the chalcogenide includes one of S, Se or Te, and the transition metal includes one of Mo or W.

Example 5 includes the subject matter of Example 1, the second transistors including respective channels, wherein: the channels of individual ones of the second transistors include the TMD material; the TMD material in individual ones of said channels includes from 1 to 5 monolayers; and individual ones of the monolayers comprise a top atomic layer, a middle atomic layer and a bottom atomic layer, the top atomic layer and the bottom atomic layer including a chalcogenide, and the middle atomic layer including a transition metal.

Example 6 includes the subject matter of Example 1, wherein the second transistors include negative metal oxide semiconductor (NMOS) transistors and positive metal oxide semiconductor (PMOS) transistors.

Example 7 includes the subject matter of Example 6, wherein the NMOS transistors include Mo and S, and the PMOS transistors include W and Se.

Example 8 includes the subject matter of Example 1, wherein the second transistors form stacked rows of transistors.

Example 9 includes the subject matter of any one of Examples 1-8, further including a back end, and a cluster of electrically conductive structures in the BEOL stack, the cluster to conduct an electrical signal a direction between the second transistors and the back end, the electrically conductive structures spaced more closely with respect to one another than a majority of other electrically conductive structures of the device that extend in the direction.

Example 10 includes the subject matter of any one of Examples 1-8, wherein the BEOL stack includes metallization layers, the device further including: a back end; a power via extending through the metallization layers in a direction between the FEOL stack and the back end; and an electrically conductive structure in the BEOL stack, the electrically conductive structure to conduct an electrical signal a direction between the second transistors and the back end and being at least as thick as the power via.

Example 11 includes the subject matter of any one of Examples 1-8, wherein the BEOL stack includes a plurality of electrically conductive structures that extend to individual corresponding ones of the second transistors.

Example 12 includes the subject matter of Example 1, the device further including a back end, wherein the BEOL stack includes electrically conductive structures extending directly from the second transistors to the back end of the die.

Example 13 includes the subject matter of any one of Examples 1-12, wherein the second transistors include metal oxide semiconductor (MOS) transistors including at least one of dual gate transistors, trigate transistors, FinFET transistors, planar FET transistors, Gate All Around cylindrical transistors, tunneling FET (TFET) transistors, Square Wire transistors, or rectangular ribbon transistors.

Example 14 includes the subject matter of Example 13, wherein the second transistors include hafnium and oxide.

Example 15 includes the subject matter of Example 13, wherein the second transistors further include dual gate transistors, individual ones of the dual gate transistors including a top gate, a back gate, a bottom gate, a first layer adjacent the bottom gate and including hafnium and oxygen, a second layer adjacent the first layer, the second layer including oxygen and at least one of silicon and aluminum.

Example 16 includes the subject matter of Example 1, wherein the FEOL stack includes circuitry coupled to gates of the second transistors at one terminal thereof, the device further including one or more capacitors, the circuitry coupled to the one or more capacitors at another terminal thereof.

Example 17 includes a semiconductor package, comprising: a package substrate; a die on the package substrate and electrically coupled thereto, the die including: a substrate; a first structure on the substrate, the first structure corresponding to a front end of line (FEOL) stack of the die and including a plurality of first transistors therein; and a second structure on the substrate, the second structure corresponding to a back end of line (BEOL) stack of the die, and including a plurality of second transistors therein, the plurality of second transistors including a transition metal dichalcogenide (TMD) material.

Example 18 includes the subject matter of Example 17, further including one or more inductors, the inductors electrically coupled to the second transistors.

Example 19 includes the subject matter of Example 18, wherein the inductors are further coupled to corresponding terminals of the second transistors.

Example 20 includes the subject matter of Example 19, further including a capacitor coupled at a terminal thereof to corresponding terminals of the second transistor.

Example 21 includes the subject matter of Example 17, wherein the BEOL stack includes metallization layers, and individual ones of the second transistor are at a level of one or more the metallization layers of the BEOL stack.

Example 22 includes the subject matter of Example 17, wherein the TMD material includes a monolayer comprising a top atomic layer, a middle atomic layer and a bottom atomic layer, the top atomic layer and the bottom atomic layer including a chalcogenide, and the middle atomic layer including a transition metal.

Example 23 includes the subject matter of Example 22, wherein the chalcogenide includes one of S, Se or Te, and the transition metal includes one of Mo or

W.

Example 24 includes the subject matter of Example 17, the second transistors including respective channels, wherein: the channels of individual ones of the second transistors include the TMD material; the TMD material in individual ones of said channels includes from 1 to 5 monolayers; and individual ones of the monolayers comprise a top atomic layer, a middle atomic layer and a bottom atomic layer, the top atomic layer and the bottom atomic layer including a chalcogenide, and the middle atomic layer including a transition metal.

Example 25 includes the subject matter of Example 17, wherein the second transistors include negative metal oxide semiconductor (NMOS) transistors and positive metal oxide semiconductor (PMOS) transistors.

Example 26 includes the subject matter of Example 25, wherein the NMOS transistors include Mo and S, and the PMOS transistors include W and Se.

Example 27 includes the subject matter of Example 17, wherein the second transistors form stacked rows of transistors.

Example 28 includes the subject matter of any one of Examples 17-27, further including a back end, and a cluster of electrically conductive structures in the BEOL stack, the cluster to conduct an electrical signal a direction between the second transistors and the back end, the electrically conductive structures spaced more closely with respect to one another than a majority of other electrically conductive structures of the die that extend in the direction.

Example 29 includes the subject matter of any one of Examples 17-27, wherein the BEOL stack includes metallization layers, the die further including: a back end; a power via extending through the metallization layers in a direction between the FEOL stack and the back end; an electrically conductive structure in the BEOL stack, the electrically conductive structure to conduct an electrical signal a direction between the second transistors and the back end and being at least as thick as the power via,

Example 30 includes the subject matter of any one of Examples 17-27, wherein the BEOL stack includes a plurality of electrically conductive structures that extend to individual corresponding ones of the second transistors.

Example 31 includes the subject matter of Example 17, the die further including a back end, wherein the BEOL stack includes electrically conductive structures extending directly from the second transistors to the back end of the die.

Example 32 includes the subject matter of any one of Examples 17-27, wherein the second transistors include metal oxide semiconductor (MOS) transistors including at least one of dual gate transistors, trigate transistors, FinFET transistors, planar FET transistors, Gate All Around cylindrical transistors, tunneling FET (TFET) transistors, Square Wire transistors, or rectangular ribbon transistors.

Example 33 includes the subject matter of Example 32, wherein the second transistors include hafnium and oxide.

Example 34 includes the subject matter of Example 32, wherein the second transistors further include dual gate transistors, individual ones of the dual gate transistors including a top gate, a back gate, a bottom gate, a first layer adjacent the bottom gate and including hafnium and oxygen, a second layer adjacent the first layer, the second layer including oxygen and at least one of silicon and aluminum.

Example 35 includes the subject matter of Example 17, wherein the FEOL stack includes circuitry coupled to gates of the second transistors at one terminal thereof, the die further including one or more capacitors, the circuitry coupled to the one or more capacitors at another terminal thereof.

Example 36 includes an integrated circuit (IC) device assembly including: a printed circuit board; a package substrate on the printed circuit board and electrically coupled thereto; and a die on the package substrate and electrically coupled thereto, the die including: a substrate; a first structure on the substrate, the first structure corresponding to a front end of line (FEOL) stack of the die and including a plurality of first transistors therein; and a second structure on the substrate, the second structure corresponding to a back end of line (BEOL) stack of the die, and including a plurality of second transistors therein, the plurality of second transistors including a transition metal dichalcogenide (TMD) material.

Example 37 includes the subject matter of Example 36, further including one or more inductors, the inductors electrically coupled to the second transistors.

Example 38 includes the subject matter of Example 37, wherein the inductors are further coupled to corresponding terminals of the second transistors.

Example 39 includes the subject matter of Example 38, further including a capacitor coupled at a terminal thereof to corresponding terminals of the second transistor.

Example 40 includes the subject matter of Example 36, wherein the BEOL stack includes metallization layers, and individual ones of the second transistor are at a level of one or more the metallization layers of the BEOL stack.

Example 41 includes the subject matter of Example 36, wherein the TMD material includes a monolayer comprising a top atomic layer, a middle atomic layer and a bottom atomic layer, the top atomic layer and the bottom atomic layer including a chalcogenide, and the middle atomic layer including a transition metal.

Example 42 includes the subject matter of Example 41, wherein the chalcogenide includes one of S, Se or Te, and the transition metal includes one of Mo or W.

Example 43 includes the subject matter of Example 36, the second transistors including respective channels, wherein: the channels of individual ones of the second transistors include the TMD material; the TMD material in individual ones of said channels includes from 1 to 5 monolayers; and individual ones of the monolayers comprise a top atomic layer, a middle atomic layer and a bottom atomic layer, the top atomic layer and the bottom atomic layer including a chalcogenide, and the middle atomic layer including a transition metal.

Example 44 includes the subject matter of Example 36, wherein the second transistors include negative metal oxide semiconductor (NMOS) transistors and positive metal oxide semiconductor (PMOS) transistors.

Example 45 includes the subject matter of Example 44, wherein the NMOS transistors include Mo and S, and the PMOS transistors include W and Se.

Example 46 includes the subject matter of Example 36, wherein the second transistors form stacked rows of transistors.

Example 47 includes the subject matter of any one of Examples 36-46, further including a back end, and a cluster of electrically conductive structures in the BEOL stack, the cluster to conduct an electrical signal a direction between the second transistors and the back end, the electrically conductive structures spaced more closely with respect to one another than a majority of other electrically conductive structures of the die that extend in the direction.

Example 48 includes the subject matter of any one of Examples 36-46, wherein the BEOL stack includes metallization layers, the die further including: a back end; a power via extending through the metallization layers in a direction between the FEOL stack and the back end; an electrically conductive structure in the BEOL stack, the electrically conductive structure to conduct an electrical signal a direction between the second transistors and the back end and being at least as thick as the power via,

Example 49 includes the subject matter of any one of Examples 36-46, wherein the BEOL stack includes a plurality of electrically conductive structures that extend to individual corresponding ones of the second transistors.

Example 50 includes the subject matter of Example 36, the die further including a back end, wherein the BEOL stack includes electrically conductive structures extending directly from the second transistors to the back end of the die.

Example 51 includes the subject matter of any one of Examples 36-46, wherein the second transistors include metal oxide semiconductor (MOS) transistors including at least one of dual gate transistors, trigate transistors, FinFET transistors, planar FET transistors, Gate All Around cylindrical transistors, tunneling FET (TFET) transistors, Square Wire transistors, or rectangular ribbon transistors.

Example 52 includes the subject matter of Example 51, wherein the second transistors include hafnium and oxide.

Example 53 includes the subject matter of Example 51, wherein the second transistors further include dual gate transistors, individual ones of the dual gate transistors including a top gate, a back gate, a bottom gate, a first layer adjacent the bottom gate and including hafnium and oxygen, a second layer adjacent the first layer, the second layer including oxygen and at least one of silicon and aluminum.

Example 54 includes the subject matter of Example 36, wherein the FEOL stack includes circuitry coupled to gates of the second transistors at one terminal thereof, the die further including one or more capacitors, the circuitry coupled to the one or more capacitors at another terminal thereof.

Example 55 includes a method to fabricate a microelectronic device including: providing a substrate; providing a first structure on the substrate, the first structure corresponding to a front end of line (FEOL) stack of the device and including a plurality of first transistors therein; and providing a second structure on the substrate, the second structure corresponding to a back end of line (BEOL) stack of the device, and including a plurality of second transistors therein, the plurality of second transistors including a transition metal dichalcogenide (TMD) material.

Example 56 includes the subject matter of Example 55, wherein the BEOL stack includes metallization layers, and individual ones of the second transistor are at a level of one or more the metallization layers of the BEOL stack.

Example 57 includes the subject matter of Example 55, wherein the TMD material includes a monolayer comprising a top atomic layer, a middle atomic layer and a bottom atomic layer, the top atomic layer and the bottom atomic layer including a chalcogenide, and the middle atomic layer including a transition metal.

Example 58 includes the subject matter of Example 57, wherein the chalcogenide includes one of S, Se or Te, and the transition metal includes one of Mo or

W.

Example 59 includes the subject matter of Example 55, the second transistors including respective channels, wherein: the channels of individual ones of the second transistors include the TMD material; the TMD material in individual ones of said channels includes from 1 to 5 monolayers; and individual ones of the monolayers comprise a top atomic layer, a middle atomic layer and a bottom atomic layer, the top atomic layer and the bottom atomic layer including a chalcogenide, and the middle atomic layer including a transition metal.

Example 60 includes the subject matter of Example 55, wherein the second transistors include negative metal oxide semiconductor (NMOS) transistors and positive metal oxide semiconductor (PMOS) transistors.

Example 61 includes the subject matter of Example 60, wherein the NMOS transistors include Mo and S, and the PMOS transistors include W and Se.

Example 62 includes the subject matter of Example 55, wherein the second transistors form stacked rows of transistors.

Example 63 includes the subject matter of any one of Examples 55-62, further including providing a back end on the BEOL stack, and a cluster of electrically conductive structures in the BEOL stack, the cluster to conduct an electrical signal a direction between the second transistors and the back end, the electrically conductive structures spaced more closely with respect to one another than a majority of other electrically conductive structures of the device that extend in the direction.

Example 64 includes the subject matter of any one of Examples 55-62, wherein the BEOL stack includes metallization layers, the method further including: providing a back end on the BEOL stack; providing a power via extending through the metallization layers in a direction between the FEOL stack and the back end; providing an electrically conductive structure in the BEOL stack, the electrically conductive structure to conduct an electrical signal a direction between the second transistors and the back end and being at least as thick as the power via,

Example 65 includes the subject matter of any one of Examples 55-62, wherein the BEOL stack includes a plurality of electrically conductive structures that extend to individual corresponding ones of the second transistors.

Example 66 includes the subject matter of Example 55, further including providing a back end on the BEOL stack, wherein the BEOL stack includes electrically conductive structures extending directly from the second transistors to the back end of the device.

Example 67 includes the subject matter of any one of Examples 55-66, wherein the second transistors include metal oxide semiconductor (MOS) transistors including at least one of dual gate transistors, trigate transistors, FinFET transistors, planar FET transistors, Gate All Around cylindrical transistors, tunneling FET (TFET) transistors, Square Wire transistors, or rectangular ribbon transistors.

Example 68 includes the subject matter of Example 67, wherein the second transistors include hafnium and oxide.

Example 69 includes the subject matter of Example 67, wherein the second transistors further include dual gate transistors, individual ones of the dual gate transistors including a top gate, a back gate, a bottom gate, a first layer adjacent the bottom gate and including hafnium and oxygen, a second layer adjacent the first layer, the second layer including oxygen and at least one of silicon and aluminum.

Example 70 includes the subject matter of Example 55, wherein the FEOL stack includes circuitry coupled to gates of the second transistors at one terminal thereof, the device further including one or more capacitors, the circuitry coupled to the one or more capacitors at another terminal thereof.

What is claimed is:

1. A microelectronic device including:
a substrate;
a first structure on the substrate, the first structure corresponding to a front end of line (FEOL) stack of the device and including a plurality of first transistors therein; and
a second structure on the substrate, the second structure corresponding to a back end of line (BEOL) stack of the device, and including a plurality of second transistors therein, the plurality of second transistors including a transition metal dichalcogenide (TMD) material.

2. The device of claim 1, wherein the BEOL stack includes metallization layers, and individual ones of the second transistor are at a level of one or more the metallization layers of the BEOL stack.

3. The device of claim 1, wherein the TMD material includes a monolayer comprising a top atomic layer, a middle atomic layer and a bottom atomic layer, the top atomic layer and the bottom atomic layer including a chalcogenide, and the middle atomic layer including a transition metal.

4. The device of claim 3, wherein the chalcogenide includes one of S, Se or Te, and the transition metal includes one of Mo or W.

5. The device of claim 1, the second transistors including respective channels, wherein:
the channels of individual ones of the second transistors include the TMD material;
the TMD material in individual ones of said channels includes from 1 to 5 monolayers; and
individual ones of the monolayers comprise a top atomic layer, a middle atomic layer and a bottom atomic layer, the top atomic layer and the bottom atomic layer including a chalcogenide, and the middle atomic layer including a transition metal.

6. The device of claim 1, wherein the second transistors include negative metal oxide semiconductor (NMOS) transistors and positive metal oxide semiconductor (PMOS) transistors.

7. The device of claim 6, wherein the NMOS transistors include Mo and S, and the PMOS transistors include W and Se.

8. The device of claim 1, wherein the second transistors form stacked rows of transistors.

9. The device of claim 1, further including a back end, and a cluster of electrically conductive structures in the BEOL stack, the cluster to conduct an electrical signal a direction between the second transistors and the back end, the electrically conductive structures spaced more closely with respect to one another than a majority of other electrically conductive structures of the device that extend in the direction.

10. The device of claim 1, wherein the BEOL stack includes metallization layers, the device further including:
a back end;
a power via extending through the metallization layers in a direction between the FEOL stack and the back end; and
an electrically conductive structure in the BEOL stack, the electrically conductive structure to conduct an electrical signal a direction between the second transistors and the back end and being at least as thick as the power via.

11. The device of claim 1, wherein the BEOL stack includes a plurality of electrically conductive structures that extend to individual corresponding ones of the second transistors.

12. The device of claim 1, the device further including a back end, wherein the BEOL stack includes electrically conductive structures extending directly from the second transistors to the back end of the device.

13. A semiconductor package, comprising:
a package substrate;
a die on the package substrate and electrically coupled thereto, the die including:
a substrate;
a first structure on the substrate, the first structure corresponding to a front end of line (FEOL) stack of the die and including a plurality of first transistors therein; and
a second structure on the substrate, the second structure corresponding to a back end of line (BEOL) stack of the die, and including a plurality of second transistors therein, the plurality of second transistors including a transition metal dichalcogenide (TMD) material.

14. The package of claim 13, further including one or more inductors, the inductors electrically coupled to the second transistors.

15. The package of claim 14, wherein the inductors are further coupled to corresponding terminals of the second transistors.

16. The package of claim 15, further including a capacitor coupled at a terminal thereof to corresponding terminals of the second transistor.

17. The package of claim 13, wherein the BEOL stack includes metallization layers, and individual ones of the second transistor are at a level of one or more the metallization layers of the BEOL stack.

18. The package of claim 13, wherein the TMD material includes a monolayer comprising a top atomic layer, a middle atomic layer and a bottom atomic layer, the top atomic layer and the bottom atomic layer including a chalcogenide, and the middle atomic layer including a transition metal.

19. An integrated circuit (IC) device assembly including:
a printed circuit board;
a package substrate on the printed circuit board and electrically coupled thereto; and
a die on the package substrate and electrically coupled thereto, the die including:
a substrate;
a first structure on the substrate, the first structure corresponding to a front end of line (FEOL) stack of the die and including a plurality of first transistors therein; and
a second structure on the substrate, the second structure corresponding to a back end of line (BEOL) stack of the die, and including a plurality of second transistors therein, the plurality of second transistors including a transition metal dichalcogenide (TMD) material.

20. The IC device assembly of claim 19, further including one or more inductors, the inductors electrically coupled to the second transistors.

21. The package of claim 20 wherein the inductors are further coupled to corresponding terminals of the second transistors.

22. The IC device assembly of claim 19, wherein the second transistors include metal oxide semiconductor (MOS) transistors including at least one of dual gate transistors, trigate transistors, FinFET transistors, planar FET transistors, Gate All Around cylindrical transistors, tunneling FET (TFET) transistors, Square Wire transistors, or rectangular ribbon transistors.

23. The IC device assembly of claim 22, wherein the second transistors further include dual gate transistors, individual ones of the dual gate transistors including a top gate, a back gate, a bottom gate, a first layer adjacent the bottom gate and including hafnium and oxygen, a second layer adjacent the first layer, the second layer including oxygen and at least one of silicon and aluminum.

24. A method to fabricate a microelectronic device including:
providing a substrate;
providing a first structure on the substrate, the first structure corresponding to a front end of line (FEOL) stack of the device and including a plurality of first transistors therein; and
providing a second structure on the substrate, the second structure corresponding to a back end of line (BEOL) stack of the device, and including a plurality of second transistors therein, the plurality of second transistors including a transition metal dichalcogenide (TMD) material.

25. The method of claim 24, wherein the BEOL stack includes metallization layers, and individual ones of the second transistor are at a level of one or more the metallization layers of the BEOL stack.
